(19) United States
(12) Patent Application Publication
(10) Pub. No.: US 2025/0199901 A1
(43) Pub. Date: Jun. 19, 2025

(54) INSPECTION PROCESSING APPARATUS AND METHOD FOR MANUFACTURING SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Takuma SUZUKI, Himeji Hyogo (JP)

(21) Appl. No.: 19/067,702

(22) Filed: Feb. 28, 2025

Related U.S. Application Data
(63) Continuation of application No. PCT/JP2024/004150, filed on Feb. 7, 2024.

(30) Foreign Application Priority Data
Aug. 31, 2023 (JP) 2023-141569

(51) Int. Cl. G06F 11/07

(52) U.S. Cl. CPC G06F 11/079; G06F 11/0727

(57) ABSTRACT

According to one embodiment, an inspection processing apparatus includes a storage and a processor. The storage is configured to store a feature value distribution including first and second feature value distribution regions related to a target device. The processor is configured to perform a current first inspection on the target device based on the first and second feature value distribution regions stored in the storage. The feature value distribution relates to a first past inspection result of a past first inspection relating to a target device, and a second past inspection result acquired by a past second inspection of the target device after the past first inspection. A first defect rate of the second past inspection result corresponding to the first feature value distribution region is higher than a second defect rate of the second past inspection result corresponding to the second feature value distribution region.

### CROSS-REFERENCE TO RELATED APPLICATIONS

This is a continuation application of International Application PCT/JP2024/004150, filed on Feb. 7, 2024. This application also claims priority to Japanese Patent Application No. 2023-141569, filed on Aug. 31, 2023. The entire contents of which are incorporated herein by reference.

### FIELD

Embodiments described herein generally relate to an inspection processing apparatus and a method for manufacturing a semiconductor device.

### BACKGROUND

For example, various inspections are performed in the manufacture of target devices such as semiconductor devices. Improvement in inspection efficiency is desired.

### BRIEF DESCRIPTION OF THE DRAWINGS

FIG. 1 is a flowchart illustrating an operation of an inspection processing apparatus according to a first embodiment; FIG. 2 is a block diagram illustrating the inspection processing apparatus according to the first embodiment;

FIG. 3 is a schematic diagram illustrating characteristics used in the operation of the inspection processing apparatus according to the first embodiment;

FIG. 4 is a schematic diagram illustrating the characteristics used in the operation of the inspection processing apparatus according to the first embodiment;

FIG. 5 is a schematic diagram illustrating results of the operation of the inspection processing apparatus according to the first embodiment;

FIG. 6 is a schematic diagram illustrating results of the operation of the inspection processing apparatus according to the first embodiment; and

FIG. 7 is a flowchart illustrating the operation of the inspection processing apparatus according to the first embodiment.

### DETAILED DESCRIPTION

According to one embodiment, an inspection processing apparatus includes a storage and a processor. The storage is configured to store a feature value distribution including a first feature value distribution region related to a target device and a second feature value distribution region related to the target device. The processor is configured to perform a current first inspection on the target device based on the first feature value distribution region and the second feature value distribution region stored in the storage. The feature value distribution relates to a first past inspection result of a past first inspection relating to a target device, and a second past inspection result. The second past inspection result is acquired by a past second inspection of the target device after the past first inspection. A first defect rate of the second past inspection result corresponding to the first feature value distribution region is higher than a second defect rate of the second past inspection result corresponding to the second feature value distribution region.

Various embodiments are described below with reference to the accompanying drawings.

In the specification and drawings, components similar to those described previously in an antecedent drawing are marked with like reference numerals, and a detailed description is omitted as appropriate.

### First Embodiment

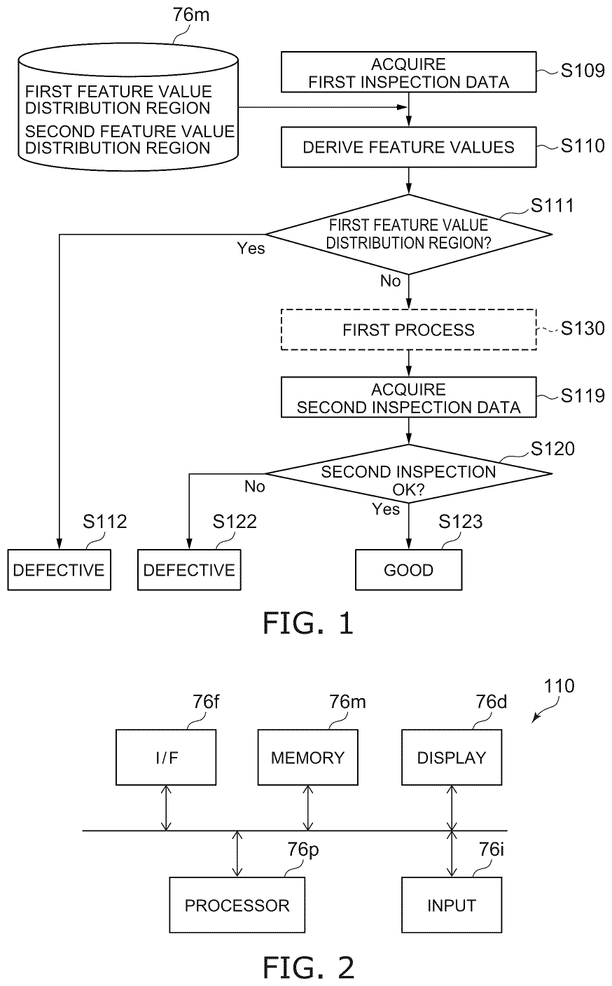

FIG. 1 is a flowchart illustrating an operation of an inspection processing apparatus according to a first embodiment.

FIG. 2 is a block diagram illustrating the inspection processing apparatus according to the first embodiment.

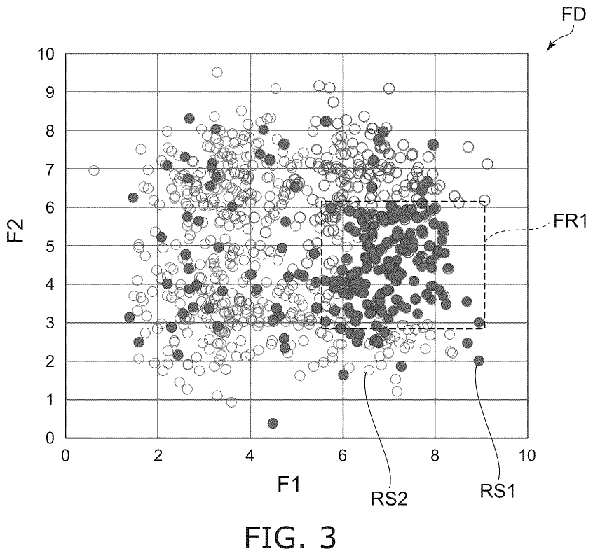

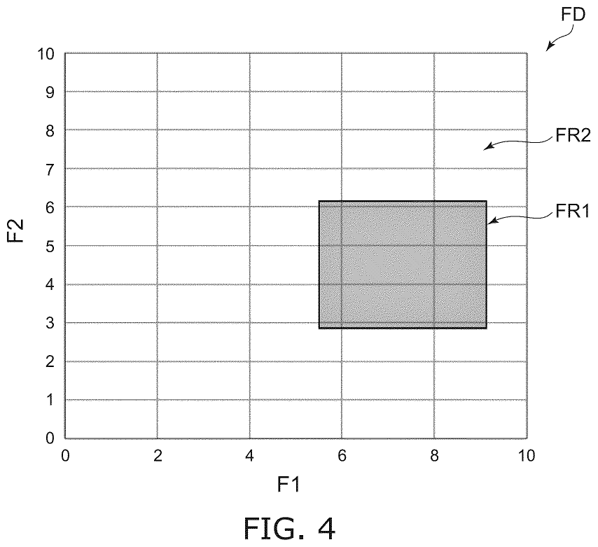

FIGS. 3 and 4 are schematic diagrams illustrating characteristics used in the operation of the inspection processing apparatus according to the first embodiment.

As shown in FIG. 2, an inspection processing apparatus 110 according to the embodiment includes a storage 76m and a processor 76p. The processor 76p may include, for example, an arithmetic device (for example, a computer). The storage 76m may include any memory (including a hard disk or the like). The inspection processing apparatus 110 may include an interface 76f, a display 76d, an input device 76i, and the like. The input device 76i may include, for example, at least one of a keyboard, a touch panel, and a mouse.

In the inspection processing apparatus 110, the storage 76m is configured to store a feature value distribution related to a target device for inspection. The target device includes, for example, various electronic devices. In one example, the target device may include a semiconductor device.

The feature value distribution includes a plurality of feature value regions related to the target device. In one example, the feature value distribution includes regions of plurality of dimensions. The region of the plurality of dimensions is divided into, for example, a plurality of partial regions. For example, the feature value distribution includes a first feature value distribution region related to the target device and a second feature value distribution region related to the target device.

FIG. 4 illustrates the feature value distribution FD. In this example, the feature value distribution FD is two-dimensional. In this example, the feature value distribution FD is represented two-dimensionally including the first feature value F1 and the second feature value F2. The feature value distribution FD is expressed by a first feature value F1 and a second feature value F2.

As shown in FIG. 4, the first feature value distribution region FR1 is one region in two-dimension. The second feature value distribution region FR2 is another region in the two- dimension. Thus, the feature value distribution FD is divided into a plurality of regions by the plurality of feature values.

The processor 76p is configured to perform a first inspection (current first inspection) on a target device (for example, a semiconductor device) based on the first feature value distribution region FR1 and the second feature value distribution region FR2 stored in the storage 76m.

In one example, when the target device is a semiconductor device, the “current first inspection” is an inspection of a crystal defect of a semiconductor included in the semiconductor device. For example, an image (such as a microscope image) indicating the crystal defect is acquired. For example, a feature value related to the shape or the like of the crystal defect may be derived from the image indicating the crystal defect. The first inspection on the target device (for example, the semiconductor device or the like) is performed based on the derived feature value. In one example, the feature value may be defined by a vector of a plurality of dimensions (for example, a value group of 128 dimensions) or the like.

The feature value distribution FD relates to a first past inspection result of a past first inspection related to a target device (for example, a semiconductor device or the like), and a second past inspection result. The second past inspection result is acquired by a past second inspection of the target device after a past first process (post-process) performed after the past first inspection. For example, the “past first inspection”, the “past first process”, and the “past second inspection” are performed in this order.

In one example, the “past first inspection” is an inspection of the crystal defect of a wafer of the semiconductor device. In one example, in the “past first process”, various processes are performed on the wafer after the first inspection is completed. The various processes include, for example, formation of a semiconductor layer, patterning, and formation of electrodes. A semiconductor device is manufactured from the wafer by the “past first process”. Thereafter, the “past second inspection” is performed. In the “past second inspection”, for example, an inspection of electrical characteristics of the semiconductor device is performed. In the “past second inspection”, an appearance inspection or the like of the semiconductor device may be performed.

There is a case where the result of the “past second inspection” is related to the result of the “past first inspection”. For example, the second past inspection result is linked to the first past inspection result. The first past inspection result and the second past inspection result are stored in the storage 76m.

FIG. 3 illustrates the feature value distribution FD. The feature value distribution FD is based on a result of the “past first inspection” and a result of the “past second inspection” regarding a target device (for example, a semiconductor device). The horizontal axis of FIG. 3 is the first feature value F1. The vertical axis of FIG. 3 is the second feature value F2. The first feature value F1 and the second feature value F2 are based on the first past inspection result and the second past inspection result. In this example, the “past first inspection” is an inspection of a crystal defect in the semiconductor device. The “past second inspection” is an inspection of electrical characteristics in the semiconductor device.

Closed circles RS1 and open circles RS2 illustrated in FIG. 3 indicate the first feature value F1 and the second feature value F2 of a defect result (for example, a crystal defect) in the “past first inspection”. The closed circles RS1 correspond to a defect (crystal defect) in the “past first inspection” and a defect (electrical characteristic abnormality) in the “past second inspection”. The open circles RS2 correspond to a defect (crystal defect) in the “past first inspection” but a good (normal electrical characteristics) in the “past second inspection”.

As illustrated in FIG. 3, in the feature value distribution FD, there is a region (first feature value distribution region FR1) in which the occurrence density of the closed circles RS1 is high. In this region, when a defect occurs in the first inspection, there is a high possibility that a defect occurs in the second inspection. A defect (crystal defect) in the first inspection included in this region is highly likely to cause a defect in the second inspection. The defect in the first inspection included in this region has a high “killer characteristic”. In the first feature value distribution region FR1, there is a high correlation between the result of the first inspection and the result of the second inspection. On the other hand, in the region excluding the first feature value distribution region FR1, the correlation between the result of the first inspection and the result of the second inspection is low.

The feature value distribution FD illustrated in FIG. 4 is obtained based on the result of the past inspection. As illustrated in FIG. 4, the feature value distribution FD includes the first feature value distribution region FR1 and the second feature value distribution region FR2. The second feature value distribution region FR2 may be, for example, a region excluding the first feature value distribution region FR1.

A first defect rate of the second past inspection result (result of the second inspection) corresponding to the first feature value distribution region FR1 is higher than a second defect rate of the second past inspection result (result of the second inspection) corresponding to the second feature value distribution region FR2. The feature value corresponding to the first feature value distribution region FR1 indicates a high possibility of defect in the second inspection. The feature value corresponding to the second feature value distribution region FR2 indicates that the possibility of defect in the second inspection is not relatively high. In the embodiment, the “current first inspection” is performed based on the first feature value distribution region FR1 and the second feature value distribution region FR2.

As illustrated in FIG. 1, in the embodiment, for example, data of the “current first inspection” is acquired (step S109). Feature values (for example, the first feature value F1 and the second feature value F2) are derived from the data of the “current first inspection” (step S110). The derived feature values are compared with the first feature value distribution region FR1 based on the past data (step S111). At this time, information on the first feature value distribution region FR1 and the second feature value distribution region FR2 is read from the storage 76m and used. Step S110 and step S111 correspond to at least a part of the “current first inspection”.

When the derived feature values are in the first feature value distribution region FR1, it is determined to be defective (step S112). For example, data (flag) indicating “defective” is output. For example, data indicating “defective” may be recorded.

By such processing, the first inspection can be performed with high efficiency. According to the embodiment, it is possible to provide an inspection processing apparatus capable of improving efficiency. The first inspection can be performed with high accuracy.

As illustrated in FIG. 1, in step S111, the first process is performed on the target device (for example, the semiconductor device) (step S130). Thereafter, the second inspection (for example, the electrical characteristic inspection) is performed, and the data of the second inspection is acquired (step S119). The data of the second inspection is compared with the determined reference, and the result of the second inspection is determined (step S120). When the result of the second inspection is defective, it is determined to be defective (step S122). When the result of the second inspection is good, it is determined to be good (step S123).

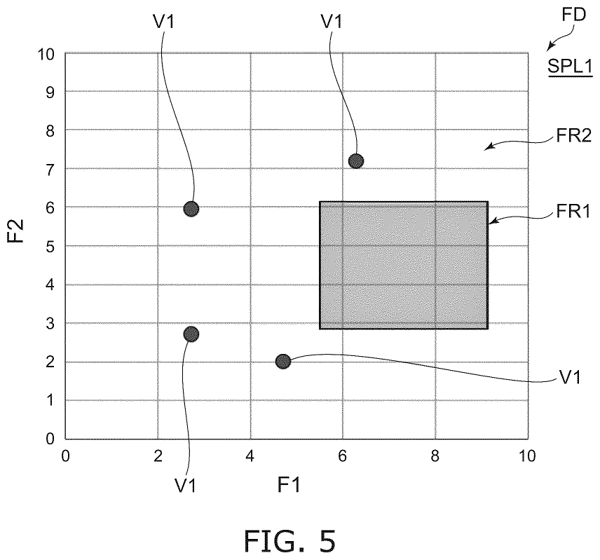

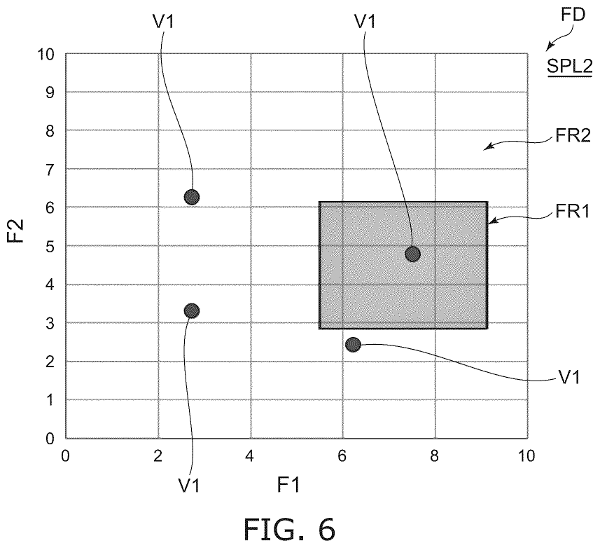

FIGS. 5 and 6 are schematic diagrams illustrating results of the operation of the inspection processing apparatus according to the first embodiment.

FIG. 5 illustrates a result of the “current first inspection” for a first sample SPL1. FIG. 6 illustrates the result of the “current first inspection” for a second sample SPL2. In this example, as shown in FIG. 5, a plurality of feature values V1 are derived in the first sample SPL1. The plurality of feature values V1 are not included in the first feature value distribution region FR1. The first sample SPL1 is determined to be good. As shown in FIG. 6, a plurality of feature values V1 are derived in the second sample SPL2. In the second sample SPL2, at least one of the plurality of feature values V1 is included in the first feature value distribution region FR1. The second sample SPL2 is determined to be defective.

In the embodiment, for example, when the result of the “current first inspection” corresponds to the first feature value distribution region FR1, the processor 76p is configured to output the determination result of the defect. When the result of the “current first inspection” corresponds to the second feature value distribution region FR2, the processor 76p is configured to not output the determination result of the defect.

The processor 76p may store the determination result in the storage 76m.

For example, the “current first inspection” and the “past first inspection” may include an image inspection of the target device. For example, the “past second inspection” may include an electrical characteristic inspection of the target device.

In one example, the target device is a semiconductor device including a semiconductor. The “current first inspection” and the “past first inspection” include an inspection of a crystal defect of the semiconductor. The “past second inspection” may include at least one of an electrical characteristic inspection of the target device (for example, the semiconductor device) or an appearance inspection of the target device (for example, the semiconductor device).

In one example, the semiconductor includes SiC. In the semiconductor device including SiC, crystal defects of SiC are likely to affect electrical characteristics. When the embodiment is applied to semiconductor devices including SiC, higher efficiency is easily obtained.

For example, the inspection of the crystal defect may include deriving a crystal defect feature value indicating a feature of an image of the crystal defect included in the semiconductor. For example, the crystal defect feature value indicates a feature of the shape of the image of the crystal defect.

The semiconductor device to which the embodiment is applied may include a plurality of semiconductor dies provided on a wafer including a semiconductor. The inspection is performed in a wafer state. The crystal defect inspection is performed on each of the plurality of semiconductor dies.

For example, the inspection of the crystal defect may include deriving a crystal defect feature value indicating a feature of an image of the crystal defect included in the semiconductor using a deep neural network (DNN). For example, the processor 76p may be further configured to derive the feature value distribution FD based on the first past inspection result and the second past inspection result.

The processor 76p may store the derived feature value distribution FD in the storage 76m.

The deriving the feature value distribution FD may include compressing the dimension of at least one of the first past inspection result and the second past inspection result. The deriving of the feature value distribution FD may include, for example, deriving the first feature value distribution region FR1 and the second feature value distribution region FR2 by processing the first past inspection result and the second past inspection result based on at least one selected from the group consisting of a Euclidean distance, a standard Euclidean distance, a Mahalanobis distance, a Manhattan distance, a Chebyshev distance, and a Minkowski distance.

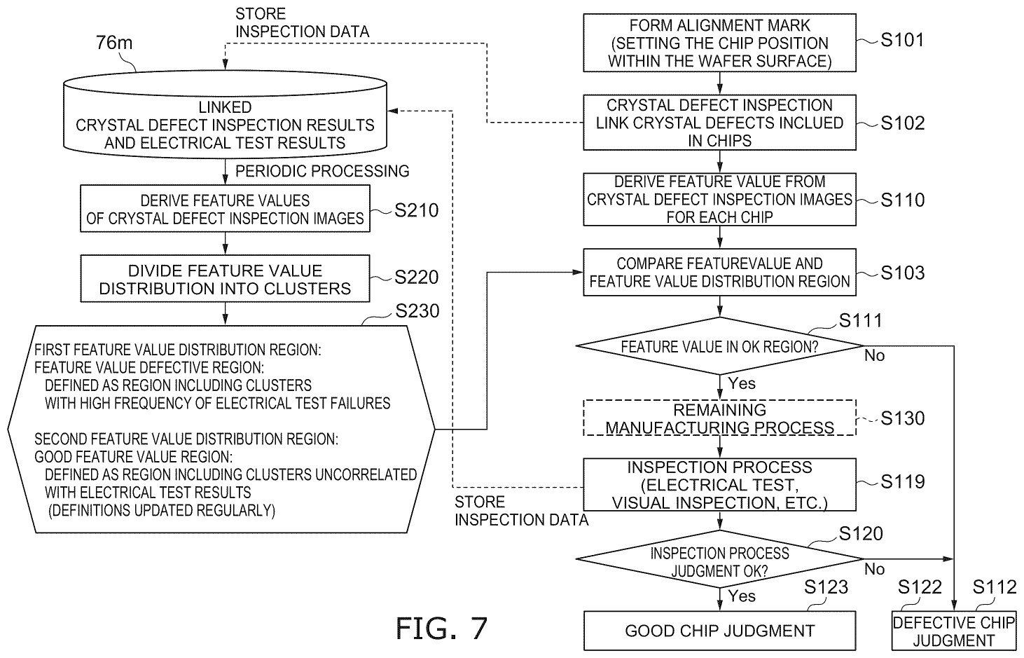

FIG. 7 is a flowchart illustrating the operation of the inspection processing apparatus according to the first embodiment.

In the example of FIG. 7, the target device is a semiconductor device including SiC. For example, in the first inspection, a wafer containing SiC is inspected. As shown in FIG. 7, an alignment mark is formed on the wafer (step S101). For example, the position of the semiconductor die in the plane of the wafer is set. For example, crystal defects of the wafer are inspected (step S102). For example, the crystal defects are linked to the position in the semiconductor die.

For example, a feature value is derived from an inspection image of crystal defects for each chip (for example, step S110). The derived feature value is compared with the feature value distribution region (first feature value distribution region FR1) (step S103). It is determined whether or not the derived feature value is in the feature value distribution region (second feature value distribution region FR2) corresponding to good (step S111). When the derived feature value is not in the feature value distribution region (second feature value distribution region FR2) corresponding to good, it is determined to be defective (step S112).

In step S111, when the derived feature value is the feature value distribution region (second feature value distribution region FR2) corresponding to good, the remaining process (first process) is performed (step S130). The inspection step (second inspection) is performed on the target device (semiconductor device) after the remaining steps (first process) are performed (step S119). Whether the result of the inspection step (second inspection) is good or bad is judged (step S120). If the result is good in step S120, the chip is judged to be a good chip (step S123). In step S120, if the result is defective, the chip is judged to be a defective chip (step S122).

In step S130 and step S111 described above, the feature value distribution FD (the first feature value distribution region FR1 and the second feature value distribution region FR2) stored in the storage 76m is used.

As shown in FIG. 7, for example, in step S230, the first feature value distribution region FR1 and the second feature value distribution region FR2 are determined. The first feature value distribution region FR1 is a region of the feature value corresponding to the state where the result of the second inspection is defective. For example, the first feature value distribution region FR1 is a region including a cluster with a high defect frequency in an electrical test.

For example, the second feature value distribution region FR2 is a region of the feature value corresponding to the result of the second inspection being good. For example, the second feature value distribution region FR2 is a region including a cluster uncorrelated with the electrical test result.

As illustrated in FIG. 7, for example, a database is stored in the storage 76m. In the database, for example, the crystal defect inspection result and the electrical test result are linked and stored for each chip. For example, feature values of the crystal defect inspection image group are derived (step S210).

For example, the derived feature value distribution FD is divided into clusters (step S220). The feature value distribution FD is divided into a plurality of regions. Thereby, the first feature value distribution region FR1 and the second feature value distribution region FR2 are determined.

As shown in FIG. 7, the inspection result of the crystal defect obtained in step S102 may be stored in the storage 76m. For example, step S210 may be performed periodically. The inspection result (the result of the second inspection) obtained in step S119 may be stored in the storage 76m.

### Second Embodiment

The second embodiment relates to a method for manufacturing a semiconductor device. In the method for manufacturing the semiconductor device according to the embodiment, for example, the first inspection is performed using the storage 76m and the processor 76p. The storage 76m is configured to store the feature value distribution FD. The feature value distribution FD includes the first feature value distribution region FR1 related to the semiconductor device and the second feature value distribution region FR2 related to the semiconductor device. The processor 76p is configured to perform the “current first inspection” on the semiconductor device based on the first feature value distribution region FR1 and the second feature value distribution region FR2 stored in the storage 76m.

The feature value distribution FD relates to the first past inspection result of the past first inspection on the semiconductor device, and the second past inspection result. The second past inspection result is acquired by the “past second inspection” of the semiconductor device after the “past first process” performed after the “past first inspection”. The second past inspection result is linked to the first past inspection result. The first defect rate of the second past inspection result corresponding to the first feature value distribution region FR1 is higher than the second defect rate of the second past inspection result corresponding to the second feature value distribution region FR2. In the embodiment, the semiconductor device can be inspected with high efficiency.

In the second embodiment, the semiconductor device includes a semiconductor. The “current first inspection” and the “past first inspection” include an inspection of the crystal defect of the semiconductor. The “past second inspection” includes at least one of an electrical characteristic inspection of the semiconductor device or an appearance inspection of the semiconductor device. The semiconductor includes, for example, SiC.

The method for manufacturing the semiconductor device according to the embodiment may further include performing the “current first process” on the semiconductor device after the “current first inspection”. The method for manufacturing the semiconductor device according to the embodiment may further include performing a “current second inspection” on the semiconductor device after the “current first process” is performed.

The embodiments may include the following Technical proposals:

### Technical Proposal 1

An inspection processing apparatus, comprising:
a storage configured to store a feature value distribution including a first feature value distribution region related to a target device and a second feature value distribution region related to the target device; and
a processor configured to perform a current first inspection on the target device based on the first feature value distribution region and the second feature value distribution region stored in the storage,
the feature value distribution relating to a first past inspection result of a past first inspection relating to a target device, and a second past inspection result,
the second past inspection result being acquired by a past second inspection of the target device after the past first inspection, and
a first defect rate of the second past inspection result corresponding to the first feature value distribution region being higher than a second defect rate of the second past inspection result corresponding to the second feature value distribution region.

### Technical Proposal 2

The inspection processing apparatus according to Technical proposal 1, wherein
the processor is configured to output a determination result of a defect if a result of the current first inspection corresponds to the first feature value distribution region, and
the processor is configured to not output the determination result of the defect if the result of the current first inspection corresponds to the second feature value distribution region.

### Technical Proposal 3

The inspection processing apparatus according to Technical proposal 1 or 2, wherein
a past first process is performed between the past first inspection and the past second inspection.

### Technical Proposal 4

The inspection processing apparatus according to any one of Technical proposals 1-3, wherein
the current first inspection and the past first inspection include an image inspection of the target device, and
the past second inspection includes an electrical characteristic inspection of the target device.

### Technical Proposal 5

The inspection processing apparatus according to any one of Technical proposals 1-3, wherein
the target device is a semiconductor device including a semiconductor,
the current first inspection and the past first inspection include an inspection of a crystal defect of the semiconductor, and
the past second inspection includes at least one of an electrical characteristic inspection of the target device or an appearance inspection of the target device.

### Technical Proposal 6

The inspection processing apparatus according to Technical proposal 5, wherein
the semiconductor includes SiC.

### Technical Proposal 7

The inspection processing apparatus according to Technical proposal 5, wherein
the inspection of the crystal defect includes deriving a crystal defect feature value indicating a feature of an image of the crystal defect included in the semiconductor.

### Technical Proposal 8

The inspection processing apparatus according to Technical proposal 7, wherein
the crystal defect feature indicates a feature of a shape of the image of the crystal defect.

### Technical Proposal 9

The inspection processing apparatus according to any one of Technical proposals 5-8, wherein
the semiconductor device includes a plurality of semiconductor dies provided on a wafer including the semiconductor, and
the inspection of the crystal defect is performed for each of the plurality of semiconductor dies.

### Technical Proposal 10

The inspection processing apparatus according to Technical proposal 5, wherein
the inspection of the crystal defect includes deriving a crystal defect feature value indicating a feature of an image of the crystal defect included in the semiconductor using a deep neural network (DNN).

### Technical Proposal 11

The inspection processing apparatus according to any one of Technical proposals 7-10, wherein
the feature distribution is two-dimensional.

### Technical Proposal 12

The inspection processing apparatus according to any one of Technical proposals 7-10, wherein
the feature value distribution is of two-dimension including a first feature value and a second feature value,
the first feature value distribution region is a region in the two-dimension, and
the second feature distribution region is another region in the two-dimension.

### Technical Proposal 13

The inspection processing apparatus according to any one of Technical proposals 1-12, wherein
the processor is configured to derive the feature value distribution based on the first past inspection result and the second past inspection result.

### Technical Proposal 14

The inspection processing apparatus according to Technical proposal 13, wherein
the processor is configured to store the feature value distribution being derived in the storage.

### Technical Proposal 15

The inspection processing apparatus according to Technical proposal 13 or 14, wherein
the deriving the feature value distribution includes compressing a dimension of at least one of the first past inspection result and the second past inspection result.

### Technical Proposal 16

The inspection processing apparatus according to any one of Technical proposals 13-15, wherein
the deriving the feature value distribution includes deriving the first feature value distribution region and the second feature value distribution region by processing the first past inspection result and the second past inspection result based on at least one selected from the group consisting of a Euclidean distance, a standard Euclidean distance, a Mahalanobis distance, a Manhattan distance, a Chebyshev distance, and a Minkowski distance.

### Technical Proposal 17

A method for manufacturing a semiconductor device, the method comprising:
performing a first inspection using a storage and a processor,
the storage being configured to store a feature value distribution including a first feature value distribution region relating to a semiconductor device and a second feature value distribution region relating to the semiconductor device,
the processor being configured to perform a current first inspection on the semiconductor device based on the first feature value distribution region and the second feature value distribution region stored in the storage,
the feature value distribution relating to a first past inspection result of a past first inspection relating to the semiconductor device, and a second past inspection result,
the second past inspection result being acquired by a past second inspection of the semiconductor device after the past first inspection, and
a first defect rate of the second past inspection result corresponding to the first feature value distribution region being higher than a second defect rate of the second past inspection result corresponding to the second feature value distribution region.

### Technical Proposal 18

The method for manufacturing the semiconductor device according to Technical proposal 17, wherein
the semiconductor device includes a semiconductor,
the current first inspection and the past first inspection include an inspection of a crystal defect of the semiconductor, and
the past second inspection includes at least one of an electrical characteristic inspection of the semiconductor device or an appearance inspection of the semiconductor device.

### Technical Proposal 19

The method for manufacturing the semiconductor device according to Technical proposal 18, wherein
the semiconductor includes SiC.

### Technical Proposal 20

The method for manufacturing the semiconductor device according to Technical proposal 17 or 18, further comprising:
performing a current first process on the semiconductor device after the current first inspection; and
performing a current second inspection on the semiconductor device after the current first processing.

According to the embodiments, it is possible to provide an inspection processing apparatus and a method for manufacturing a semiconductor device capable of improving efficiency.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the inspection processing apparatuses such as storages, processors, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all inspection processing apparatuses and all methods for manufacturing semiconductor devices practicable by an appropriate design modification by one skilled in the art based on the inspection processing apparatuses and the methods for manufacturing semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An inspection processing apparatus, comprising:
a storage configured to store a feature value distribution including a first feature value distribution region related to a target device and a second feature value distribution region related to the target device; and
a processor configured to perform a current first inspection on the target device based on the first feature value distribution region and the second feature value distribution region stored in the storage,
the feature value distribution relating to a first past inspection result of a past first inspection relating to a target device, and a second past inspection result
the second past inspection result being acquired by a past second inspection of the target device after the past first inspection, and
a first defect rate of the second past inspection result corresponding to the first feature value distribution region being higher than a second defect rate of the second past inspection result corresponding to the second feature value distribution region.

2. The apparatus according to claim 1, wherein
the processor is configured to output a determination result of a defect if a result of the current first inspection corresponds to the first feature value distribution region, and
the processor is configured to not output the determination result of the defect if the result of the current first inspection corresponds to the second feature value distribution region.

3. The apparatus according to claim 1, wherein
a past first process is performed between the past first inspection and the past second inspection.

4. The apparatus according to claim 1, wherein
the current first inspection and the past first inspection include an image inspection of the target device, and
the past second inspection includes an electrical characteristic inspection of the target device.

5. The apparatus according to claim 1, wherein
the target device is a semiconductor device including a semiconductor,
the current first inspection and the past first inspection include an inspection of a crystal defect of the semiconductor, and
the past second inspection includes at least one of an electrical characteristic inspection of the target device or an appearance inspection of the target device.

6. The apparatus according to claim 5, wherein
the semiconductor includes SiC.

7. The apparatus according to claim 5, wherein
the inspection of the crystal defect includes deriving a crystal defect feature value indicating a feature of an image of the crystal defect included in the semiconductor.

8. The apparatus according to claim 7, wherein
the crystal defect feature indicates a feature of a shape of the image of the crystal defect.

9. The apparatus according to claim 5, wherein
the semiconductor device includes a plurality of semiconductor dies provided on a wafer including the semiconductor, and
the inspection of the crystal defect is performed for each of the plurality of semiconductor dies.

10. The apparatus according to claim 5, wherein
the inspection of the crystal defect includes deriving a crystal defect feature value indicating a feature of an image of the crystal defect included in the semiconductor using a deep neural network (DNN).

11. The apparatus according to claim 7, wherein
the feature distribution is two-dimensional.

12. The apparatus according to claim 7, wherein
the feature value distribution is of two-dimension including a first feature value and a second feature value,
the first feature value distribution region is a region in the two-dimension, and
the second feature distribution region is another region in the two-dimension.

13. The apparatus according to claim 1, wherein
the processor is configured to derive the feature value distribution based on the first past inspection result and the second past inspection result.

14. The apparatus according to claim 13, wherein
the processor is configured to store the feature value distribution being derived in the storage.

15. The apparatus according to claim 13, wherein
the deriving the feature value distribution includes compressing a dimension of at least one of the first past inspection result and the second past inspection result.

16. The apparatus according to claim 13, wherein
the deriving the feature value distribution includes deriving the first feature value distribution region and the second feature value distribution region by processing the first past inspection result and the second past inspection result based on at least one selected from the group consisting of a Euclidean distance, a standard Euclidean distance, a Mahalanobis distance, a Manhattan distance, a Chebyshev distance, and a Minkowski distance.

17. A method for manufacturing a semiconductor device, the method comprising:
performing a first inspection using a storage and a processor,
the storage being configured to store a feature value distribution including a first feature value distribution region relating to a semiconductor device and a second feature value distribution region relating to the semiconductor device,
the processor being configured to perform a current first inspection on the semiconductor device based on the first feature value distribution region and the second feature value distribution region stored in the storage,
the feature value distribution relating to a first past inspection result of a past first inspection relating to the semiconductor device, and a second past inspection result,
the second past inspection result being acquired by a past second inspection of the semiconductor device after the past first inspection, and
a first defect rate of the second past inspection result corresponding to the first feature value distribution region being higher than a second defect rate of the second past inspection result corresponding to the second feature value distribution region.

18. The method for manufacturing the semiconductor device according to claim 17, wherein
the semiconductor device includes a semiconductor,
the current first inspection and the past first inspection include an inspection of a crystal defect of the semiconductor, and
the past second inspection includes at least one of an electrical characteristic inspection of the semiconductor device or an appearance inspection of the semiconductor device.

19. The method for manufacturing the semiconductor device according to claim 18, wherein
the semiconductor includes SiC.

20. The method for manufacturing the semiconductor device according to claim 17, further comprising:
performing a current first process on the semiconductor device after the current first inspection; and
performing a current second inspection on the semiconductor device after the current first processing.
